(19) United States
(12) Patent Application Publication
(10) Pub. No.: US 2026/0118442 A1
(43) Pub. Date: Apr. 30, 2026

(54) METHOD AND APPARATUS FOR PREDICTING LIFE DETERIORATION POINT OF BATTERY, AND BATTERY PACK

(71) Applicant: SAMSUNG SDI CO., LTD., Yongin-si (KR)

(72) Inventors: Haemin KIM, Yongin-si (KR); Dongryul LEE, Yongin-si (KR); Junho JANG, Yongin-si (KR); Younghoon KO, Yongin-si (KR); Sangkoan YI, Yongin-si (KR); Yujin LEE, Yongin-si (KR); Youngwoong KWON, Yongin-si (KR)

(73) Assignee: SAMSUNG SDI CO., LTD., Yongin-si (KR)

(21) Appl. No.: 19/355,191

(22) Filed: Oct. 10, 2025

(30) Foreign Application Priority Data
Oct. 29, 2024 (KR) 10-2024-0150144

(51) Int. Cl. G01R 31/392; G01R 31/3835; G01R 31/389; G01R 31/396; H01M 10/42; H01M 10/48

(52) U.S. Cl. CPC G01R 31/392; G01R 31/3835; G01R 31/389; G01R 31/396; H01M 10/425; H01M 10/482; H01M 2010/4271

(57) ABSTRACT

A method for predicting a life deterioration point of a battery may be provided. The method for predicting a life deterioration point of a battery includes estimating a state of health (SoH) of a battery cell in each of a plurality of charge/discharge cycles, calculating a differentiation value representing a change in SoH of the battery cell in each of the plurality of charge/discharge cycles, calculating a threshold value for predicting the life deterioration point of the battery cell, and determining a point in time, at which an SoH differentiation curve representing the differentiation value of the battery cell for each of the plurality of charge/discharge cycles and the threshold value meet, as the life deterioration point of the battery cell.

### CROSS-REFERENCE TO RELATED APPLICATION

This application claims priority to Korean Patent Application No. 10-2024-0150144 filed with the Korean Intellectual Property Office on Oct. 29, 2024, the entire contents of which are incorporated herein by reference.

### BACKGROUND

### (a) Field

This disclosure relates to a method and apparatus for predicting a life deterioration point of battery, and a battery pack.

### (b) Description of the Related Art

As a battery is used, the state of health (SoH), which indicates the life of the battery, typically decreases. The SoH decreases substantially linearly up to a certain point, but decreases non-linearly after a certain point. Therefore, the battery life tends to decrease rapidly after a certain point. The point at which SoH decreases non-linearly is called a life deterioration point (onset point).

When presenting performance related to battery life characteristics, it is useful to present EOL (end of life) or ensure that substantially no deterioration occurs within a certain charging/discharging cycle. Accordingly, the life deterioration point of SoH may be used as an indicator in battery life characteristics.

### SUMMARY

At least one example embodiment of the present disclosure includes a method and apparatus for predicting a life deterioration point of a battery, and a battery pack configured to predict a life deterioration point of a battery cell.

According to one example embodiment, a method for predicting a life deterioration point of a battery may be provided. The method for predicting a life deterioration point of a battery includes estimating a state of health (SoH) of a battery cell in each of a plurality of charge/discharge cycles; calculating a differentiation value representing a change in SoH of the battery cell in each of the plurality of charge/discharge cycles; calculating a threshold value for predicting the life deterioration point of the battery cell; and determining a point in time at which an SoH differentiation curve representing the differentiation value of the battery cell for each of the plurality of charge/discharge cycles and the threshold value meet as the life deterioration point of the battery cell.

The calculating a threshold value may include calculating the threshold value using differentiation values within a set charge/discharge cycle period of the SoH differentiation curve.

The set charge/discharge cycle period may include a period from a first charge/discharge cycle of the plurality of charge/discharge cycles or a charge/discharge cycle after an initial part of the plurality of charge/discharge cycles including at least the first charge/discharge cycle to a charge/discharge cycle before derating occurs.

The calculating the threshold value using the differentiation values within a set charge/discharge cycle period may include setting an average value of the differentiation values of the set charge/discharge cycle period as the threshold value.

The method for predicting a life deterioration point of a battery may further include filtering the SoH differentiation curve.

The filtering may include using at least one of a gaussian filter and a bilateral filter.

According to another example embodiment, an apparatus for predicting a life deterioration point of a battery may be provided. The apparatus for predicting a life deterioration point of a battery includes a battery cell configured to be charged or discharged according to a plurality of charge/discharge cycles; a measurement meter configured to measure a characteristic value of the battery cell in each of the plurality of charge/discharge cycles; and a controller configured to estimate a state of health (SoH) of the battery cell for each of the plurality of charge/discharge cycles using the characteristic value of the battery cell measured in each of the plurality of charge/discharge cycles, generate an SoH differentiation curve representing a differentiation value of the SoH in each of the plurality of charge/discharge cycles, and determine a point in time at which the SoH differentiation curve and a threshold value for predicting the life deterioration point of the battery cell meet as the life deterioration point of the battery cell.

The controller may be configured to set an average value of the differentiation values within a set charge/discharge cycle period of the SoH differentiation curve as the threshold value.

The set charge/discharge cycle period may include a period from a first charge/discharge cycle of the plurality of charge/discharge cycles, or a charge/discharge cycle after an initial part of the plurality of charge/discharge cycles including at least the first charge/discharge cycle, to a charge/discharge cycle before derating occurs.

The controller may be configured to filter the SoH differentiation curve before determining the life deterioration point of the battery cell.

The characteristic value may include at least one of the discharge capacity, internal resistance, and open circuit voltage (OCV) of the battery cell.

According to another example embodiment, a battery pack may be provided. The battery pack includes a battery module configured to comprise at least one battery cell; a switch configured to be connected to the battery module according to plurality of charge/discharge cycles; and a battery life depletion prediction apparatus configured to measure a characteristic value of the battery cell in each of the plurality of charge/discharge cycles, estimate a state of health (SoH) of the battery cell for each of the plurality of charge/discharge cycles using the characteristic value of the battery cell measured in each of the plurality of charge/discharge cycles, generate an SoH differentiation curve representing a differentiation value of the SoH in each of the plurality of charge/discharge cycles, and determine a point in time, at which the SoH differentiation curve and a threshold value for predicting the life deterioration point of the battery cell meet, as the life deterioration point of the battery cell.

The battery life depletion prediction apparatus may be configured to set an average value of the differentiation values within a set charge/discharge cycle period of the SoH differentiation curve as the threshold value.

The set charge/discharge cycle period may include a period from a first charge/discharge cycle of the plurality of charge/discharge cycles or a charge/discharge cycle after an initial part of the plurality of charge/discharge cycles including at least the first charge/discharge cycle to a charge/discharge cycle before derating occurs.

The battery pack may further include a battery management system configured to control the switch and the battery module according to the plurality of charge/discharge cycles.

### BRIEF DESCRIPTION OF THE DRAWINGS

FIG. 1 is a diagram illustrating a battery life deterioration point prediction apparatus, according to one example embodiment.

FIG. 2 is a flowchart illustrating a method for predicting a life deterioration point of a battery, according to an example embodiment.

FIG. 3 is a diagram showing an example of a SoH curve, according to an example embodiment.

FIG. 4 is a diagram showing an example of a SoH differentiation curve, according to an example embodiment.

FIG. 5 is a diagram showing an example of a filtered SoH differentiation curve, according to an example embodiment.

FIG. 6 is a drawing explaining a method for determining a threshold value, according to an example embodiment.

FIG. 7 is a diagram showing a life deterioration point of a battery cell, according to an example embodiment.

FIG. 8 is a diagram showing an example of a battery pack to which a battery life deterioration point prediction apparatus according to one example embodiment is applied.

FIG. 9 is a diagram illustrating a battery life deterioration point prediction apparatus, according to another example embodiment.

### DETAILED DESCRIPTION OF THE EMBODIMENTS

Example embodiments are described more fully hereinafter with reference to the accompanying drawings; however, the example embodiments may be embodied in different forms and should not be construed as limited to the example embodiments set forth herein. Rather, these example embodiments are provided so that this disclosure is thorough and complete, and fully conveys example implementations to those skilled in the art. The drawings and description are to be regarded as illustrative in nature and not restrictive. Like reference numerals designate like elements throughout the specification. In the flowchart described with reference to the drawings in this specification, the order of operations may be changed, several operations may be merged, some operations may be divided, and specific operations may not be performed.

Throughout the specification and claims, when a part is referred to “include” a certain element, it may mean that the part may further include other elements rather than exclude other elements, unless specifically indicated otherwise.

In addition, expressions described in the singular may be interpreted in the singular or plural unless explicit expressions such as “one” or “single” are used.

In addition, terms including an ordinal number, such as first, second, and the like, may be used to describe various elements, but the elements are not limited by the terms. The above terms are used only for the purpose of distinguishing one element from another element. For example, without departing from the scope of the present disclosure, a first element may be referred to as a second element, and similarly, a second element may be referred to as a first element.

Furthermore, when a component is referred to be “connected” with another component, it includes not only the case where two components are “directly connected” but also the case where two components are “indirectly or non-contactedly connected” with another component interposed therebetween, or the case where two components are “electrically connected.” On the other hand, when an element is referred to as “directly connected” to another element, it should be understood that no other element exists in the middle.

When the term “substantially” is used in this specification in connection with a numerical value, it is intended that the associated numerical value include a tolerance of ±10% around the stated numerical value. The expression “up to” includes amounts of zero to the expressed upper limit and all values therebetween.

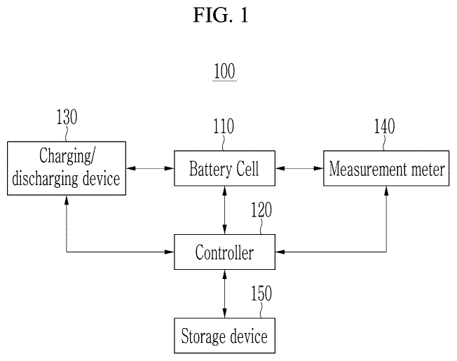

FIG. 1 is a diagram illustrating a battery life deterioration point prediction apparatus, according to one example embodiment.

Referring to FIG. 1, a battery life deterioration point prediction apparatus 100 may be configured to predict the life deterioration point of a battery cell 110 and may include a controller 120, a charging/discharging device 130, a measurement meter 140, and a storage device 150.

The battery cell 110 may be stored within the chamber.

The charging/discharging device 130 may be configured to charge or discharge the battery cell 110 based on a control signal of the controller 120.

The controller 120 may be configured to generate the control signal for controlling the charging/discharging device 130 according to the charge/discharge cycle and transmit the control signal to the charging/discharging device 130. In addition, the controller 120 may transmit a control signal to the measurement meter 140 to measure characteristic values for each charge/discharge cycle. A single charge/discharge cycle may include, e.g., a charge period, a rest period, a discharge period, and a rest period.

The charging/discharging device 130 may be configured to charge the battery cell 110 in the charge period.

The charging/discharging device 130 may be configured to discharge the battery cell 110 in the discharge period. The rest period may be a period for stabilizing the battery cell 110.

The measurement meter 140 may be configured to measure the characteristic value of the battery cell 110 for each charge/discharge cycle based on the measurement control signal of the controller 120, and transmit the characteristic value of the battery cell 110 to the controller 120. The measured characteristic values may be stored in the storage device 150.

The controller 120 may be configured to estimate the state of health (SoH) for each charge/discharge cycle based on the characteristic values for each charge/discharge cycle measured by the measurement meter 140, and may generate an SoH curve representing the SoH for each charge/discharge cycle.

The SoH is a desired indicator of the life of a battery cell 110. The SoH may be expressed as a percentage of the capacity reduction compared to the initial capacity, and may be used as an indicator of performance deterioration due to aging.

The controller 120 may estimate SoH for each charge/discharge cycle by, e.g., performing a capacity test for each charge/discharge cycle. The battery cell 110 may be charged and then discharged in each charge/discharge cycle.

According to some example embodiments, the characteristic value of the battery cell 110 measured by the measurement meter 140 may be the discharge capacity, e.g., the amount of electron charge emitted during discharge of the battery cell 110 in the discharge period of each charge/discharge cycle, and the controller may estimate the discharge capacity of the battery cell 110 for each charge/discharge cycle, and may estimate the SoH of the battery cell 110 for each charge/discharge cycle using the discharge capacity of the battery cell 110 for each charge/discharge cycle.

In addition, the SoH deteriorates as the number of charge/discharge cycles of the battery cell 110 increases, which may lead to a decrease in the capacity of the battery cell 110 and an increase in the internal resistance.

According to some example embodiments, the characteristic value of the battery cell 110 measured by the measurement meter 140 may include the internal resistance of the battery cell 110. The controller 120 may estimate the SoH of the battery cell 110 for each charge/discharge cycle by using the internal resistance of the battery cell 110 for each charge/discharge cycle.

In some example embodiments, the characteristic values of the battery cell 110 measured by the measurement meter 140 may include the open circuit voltage (OCV) of the battery cell 110 for each charge/discharge cycle. The controller 120 may estimate the SoH of the battery cell 110 for each charge/discharge cycle by using the OCV of the battery cell 110 for each charge/discharge cycle. The controller 120 may estimate the impedance for each charge/discharge cycle from the OCV for each charge/discharge cycle by utilizing the principle that the OCV changes as the battery ages, and may estimate the SoH of the battery cell 110 for each charge/discharge cycle based on the impedance for each charge/discharge cycle.

The controller 120 may generate a SoH differentiation curve that represents the change in the SoH for each charge/discharge cycle, and may calculate a threshold value for predicting the life deterioration point of the battery cell 110 using the SoH differentiation curve. The change in the SoH for each charge/discharge cycle may represent the difference between the SOH in each charge/discharge cycle and the SOH in the previous cycle.

The controller 120 may determine a first point in time, at which the SoH differentiation curve and the calculated threshold value first meet, as the life deterioration point of the battery cell 110.

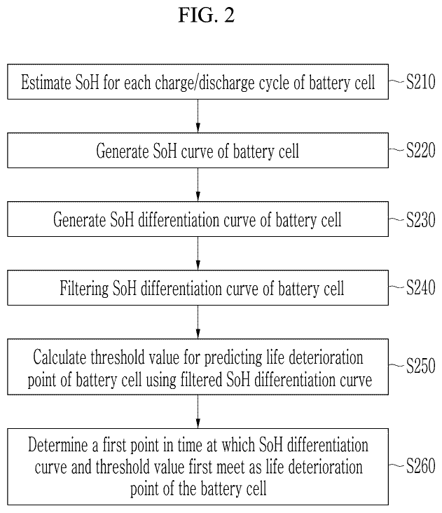

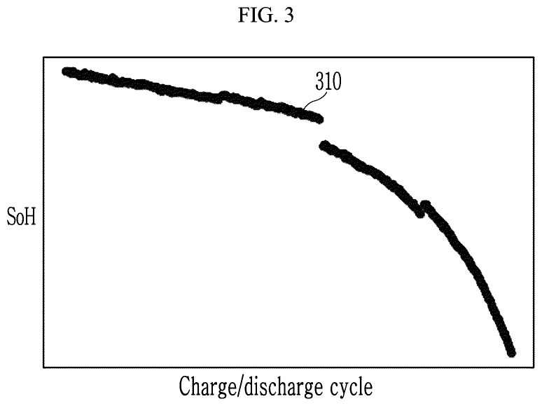

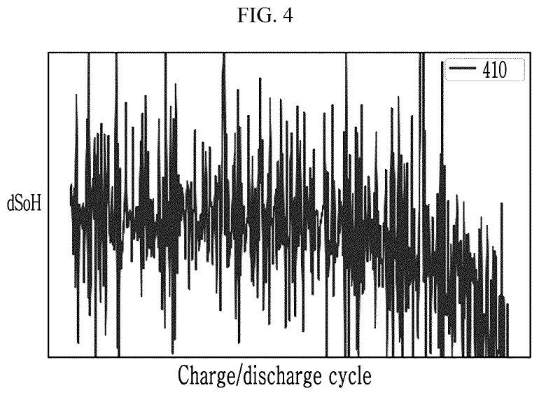

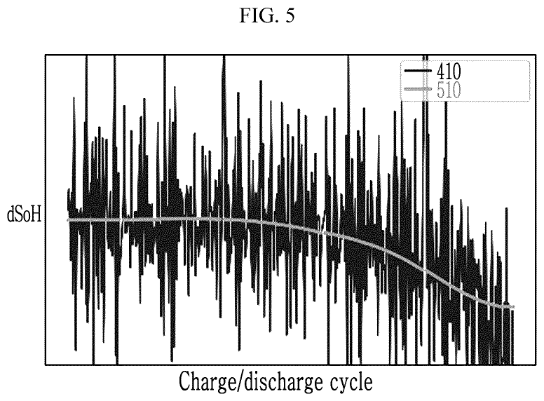

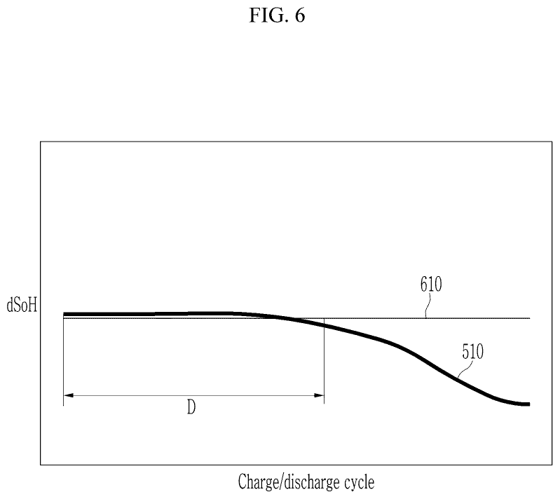

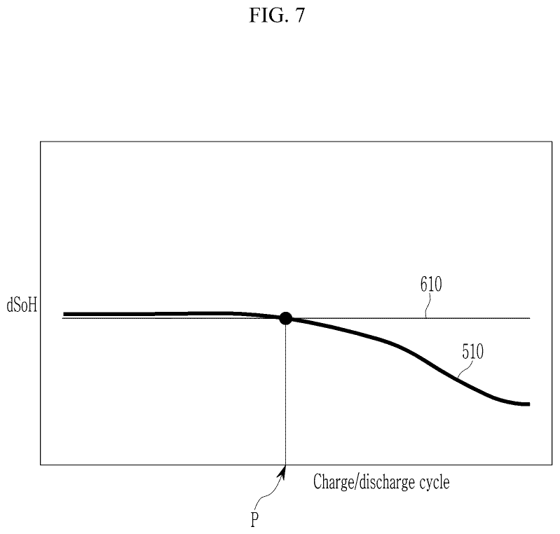

FIG. 2 is a flowchart illustrating a method for predicting a life deterioration point of a battery, according to an example embodiment. FIG. 3 is a diagram showing an example of a SoH curve, according to an example embodiment, FIG. 4 is a diagram showing an example of a SoH differentiation curve, according to an example embodiment, and FIG. 5 is a diagram showing an example of a filtered SoH differentiation curve, according to an example embodiment. FIG. 6 is a drawing explaining a method for determining a threshold value, according to an example embodiment, and FIG. 7 is a diagram showing a life deterioration point of a battery cell, according to an example embodiment.

Referring to FIG. 2 and FIG. 3, the controller 120 may estimate SoH for each charge/discharge cycle of the battery cell 110 based on characteristic value for each charge/discharge cycle measured by the measurement meter 140 (S210), and may generate an SoH curve 310 representing SoH for each charge/discharge cycle for the battery cell 110 (S220), as shown in FIG. 3.

Referring to FIG. 2 and FIG. 4, the controller may generate an SoH differentiation curve 410 representing a change dSoH in SoH for each charge/discharge cycle for the battery cell 110 from the SoH curve 310 representing SoH for each charge/discharge cycle (S230). The SoH differentiation curve 410 may include a differentiation value which is the change dSoH in SoH for each charge/discharge cycle.

Referring to FIG. 2 and FIG. 5, the controller may generate a filtered SoH differentiation curve 510 by filtering the SoH differentiation curve 410 (S240). The controller 120 may remove noise from the SoH differentiation curve 410 by filtering the SoH differentiation curve 410.

In some example embodiments, filtering may use, e.g., at least one of a Gaussian filter and a bilateral filter.

Next, referring to FIG. 2 and FIG. 6, the controller may calculate a threshold value 610 for predicting the life deterioration point of the battery cell 110 using the filtered SoH differentiation curve 510 (S250).

In some example embodiments, the controller 120 may calculate the threshold value 610 using the SoH differentiation value within a set period D from the filtered SoH differentiation curve (510).

In some example embodiments, the controller 120 may calculate an average value of the SoH differentiation value for each charge/discharge cycle within the set period D, and set the average value of the SoH differentiation value as the threshold value 610.

The set period D may include a portion of the entire charge/discharge cycle.

In some example embodiments, the set period D may include a period from the start charge/discharge cycle of the entire charge/discharge cycle to the 200th charge/discharge cycle. The set period D may include a period from the start of the entire charge/discharge cycle to a charge/discharge cycle before a first derating occurs without any rapid or substantial deterioration of the battery life.

In some other example embodiments, the set period D may include a period from when the battery cell 110 begins to operate stably to the charge/discharge cycle before the first derating occurs. In the initial part (e.g., the 1st to 30th charge/discharge cycle) of the entire charge/discharge cycle, the SoH of the battery cell 110 may not be stable. Accordingly, the set period D may be set as a period from a charge/discharge cycle after the initial part to a charge/discharge cycle before a first derating occurs, and for example, the set period D may include a period from the 31st charge/discharge cycle to the 200th charge/discharge cycle. Herein, it is assumed that the 200th charge/discharge cycle is the charge/discharge cycle before the first derating occurred.

Referring to FIG. 2 and FIG. 7, when the threshold value 610 is determined, the controller 120 may determine a first point in time P, at which the SoH differentiation curve and the calculated threshold value 610 first meet, as the life deterioration point of the battery cell (S260).

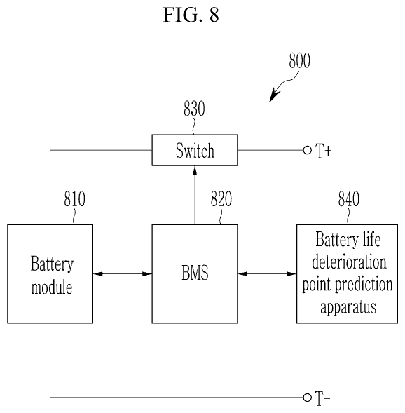

FIG. 8 is a diagram showing an example of a battery pack to which a battery life deterioration point prediction apparatus according to one example embodiment is applied.

Referring to FIG. 8, a battery pack 800 may include at least one battery module 810, a battery management system (BMS) 820, a switch 830, and a battery life deterioration point prediction apparatus 840.

In some example embodiments, the battery life deterioration point prediction apparatus 840 may be implemented within the BMS 820.

The battery pack 800 may be connected to the charging/discharging device (130 in FIG. 1) of the battery life deterioration point prediction apparatus 840 through terminals T+ and T−.

The at least one battery module 810 may include a plurality of battery cells electrically connected to each other in series and/or in parallel.

The switch 830 may be configured to control the current path during charging/discharging of the battery module 810. Closing and opening of the switch 830 may be controlled according to a switch control signal output from the BMS 820.

The BMS 820 may control and manage the overall operation of the battery pack 800. The BMS 820 may collect the overall status information of the battery module 110 and the battery cells included in the battery module 810, and monitor the overall status of the battery module 810 and the battery cells included in the battery module 810.

The BMS 820 may be configured to perform various control functions to adjust the status of the battery module 810, and the battery cells included in the battery module 810, based on the status information of the battery module 810 and the battery cells included in the battery module 810. As an example, the BMS 820 may control the charge/discharge current of the battery module 810 based on the status information such as a plurality of battery cell voltages, battery current, and the like, and perform cell balancing operations for the plurality of battery cells.

The battery life deterioration point prediction apparatus 840 may be configured to control the battery module 810 through the BMS 820.

The battery life deterioration point prediction apparatus 840 may estimate SoH for each charge/discharge cycle based on the characteristic value measured for each charge/discharge cycle, for each battery cell included in the battery module 810, and may generate an SoH curve representing SoH for each charge/discharge cycle, for each battery cell. The battery life deterioration point prediction apparatus 840 may determine the life deterioration point for each battery cell included in the battery module 810 based on the method described with reference to FIG. 2 to FIG. 7.

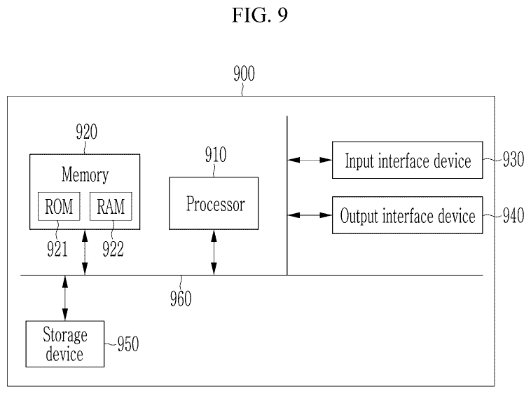

FIG. 9 is a diagram illustrating a battery life deterioration point prediction apparatus, according to another example embodiment.

Referring to FIG. 9, the battery life deterioration point prediction apparatus 900 may represent a computing device in which the method for predicting the life deterioration point of the battery described above is implemented.

The battery life deterioration point prediction apparatus 900 may include at least one of a processor 910, a memory 920, an input interface device 930, an output interface device 940, and a storage device 950. Each component is connected to a bus 960 and may communicate with each other. In addition, each component may be connected through an individual interface or individual bus centered on the processor 910, rather than the common bus 960.

The processor 910 may be implemented as one of various types of processors such as an application processor (AP), a central processing unit (CPU), a graphics processing unit (GPU), and the like, and may be or include any semiconductor device configured to execute a command stored in the memory 920 or the storage device 950. The processor 910 may perform the battery life deterioration point prediction function and operation described with reference to FIG. 1 to FIG. 8 by executing program commands stored in at least one of the memory 920 and the storage device 950.

The memory 920 and storage device 950 may include various forms of volatile or non-volatile storage media. For example, the memory 920 may include a read-only memory (ROM) 921 and a random access memory (RAM) 922. In an example embodiment, the memory 920 may be located inside or outside the processor 910, and the memory 920 may be connected to the processor 910 via various techniques already known.

The input interface device 930 may be configured to provide data to the processor 910. In some example embodiments, the input interface device 930 may provide the initial capacity and discharge capacity for each charge/discharge cycle of the battery cell 110 to the processor 910.

The output interface device 940 may be configured to output data from the processor 910. In some example embodiments, the output interface device 940 may output the life deterioration point of the battery cell 110.

According to at least one of the example embodiments, it is possible to quantitatively predict the life deterioration point of the battery.

Example embodiments have been disclosed herein, and although specific terms are employed, these terms are used and are to be interpreted in a generic and descriptive sense only, and not for purpose of limitation. In some instances, as would be apparent to one of ordinary skill in the art as of the filing of the present application, features, characteristics, and/or elements described in connection with a particular example embodiment may be used singly or in combination with features, characteristics, and/or elements described in connection with other example embodiments unless otherwise specifically indicated. Accordingly, it is understood by those of skill in the art that various changes in form and details may be made without departing from the spirit and scope of the present disclosure as set forth in the following claims.

### DESCRIPTION OF SYMBOLS

100, 840: Battery life depletion prediction apparatus
110: Battery Cell
120: Charging and discharging device
130: Measurement meter
140: Controller
150: Storage device
810: Battery module
820: BMS
830: Switch

What is claimed is:

1. A method for predicting a life deterioration point of a battery, the method comprising:
estimating a state of health (SoH) of a battery cell in each of a plurality of charge/discharge cycles;
calculating a differentiation value representing a change in SoH of the battery cell in each of the plurality of charge/discharge cycles;
calculating a threshold value for predicting the life deterioration point of the battery cell; and
determining a point in time at which an SoH differentiation curve representing the differentiation value of the battery cell for each of the plurality of charge/discharge cycles and the threshold value meet as the life deterioration point of the battery cell.

2. The method as claimed in claim 1, wherein the calculating the threshold value comprises calculating the threshold value using differentiation values within a set charge/discharge cycle period of the SoH differentiation curve.

3. The method as claimed in claim 2, wherein the set charge/discharge cycle period comprises a period from a first charge/discharge cycle of the plurality of charge/discharge cycles or a charge/discharge cycle after an initial part of the plurality of charge/discharge cycles including at least the first charge/discharge cycle to a charge/discharge cycle before derating occurs.

4. The method as claimed in claim 2, wherein the calculating the threshold value using the differentiation values within a set charge/discharge cycle period comprises setting an average value of the differentiation values of the set charge/discharge cycle period as the threshold value.

5. The method as claimed in claim 2, further comprising filtering the SoH differentiation curve.

6. The method as claimed in claim 5, wherein the filtering comprises using at least one of a gaussian filter and a bilateral filter.

7. An apparatus for predicting a life deterioration point of a battery, the apparatus comprising:
a battery cell configured to be charged or discharged according to a plurality of charge/discharge cycles;
a measurement meter configured to measure a characteristic value of the battery cell in each of the plurality of charge/discharge cycles; and
a controller configured to:
estimate a state of health (SoH) of the battery cell for each of the plurality of charge/discharge cycles based on the characteristic value of the battery cell measured in each of the plurality of charge/discharge cycles,
generate an SoH differentiation curve representing a differentiation value of the SoH in each of the plurality of charge/discharge cycles, and
determine a point in time at which the SoH differentiation curve and a threshold value for predicting the life deterioration point of the battery cell meet as the life deterioration point of the battery cell.

8. The apparatus as claimed in claim 7, wherein the controller is configured to set an average value of the differentiation values within a set charge/discharge cycle period of the SoH differentiation curve as the threshold value.

9. The apparatus as claimed in claim 8, wherein the set charge/discharge cycle period comprises a period from a first charge/discharge cycle of the plurality of charge/discharge cycles, or a charge/discharge cycle after an initial part of the plurality of charge/discharge cycles including at least the first charge/discharge cycle, to a charge/discharge cycle before derating occurs.

10. The apparatus as claimed in claim 7, wherein the controller is configured to filter the SoH differentiation curve before determining the life deterioration point of the battery cell.

11. The apparatus as claimed in claim 7, wherein the characteristic value comprises at least one of the discharge capacity, internal resistance, and open circuit voltage (OCV) of the battery cell.

12. A battery pack comprising:
a battery module comprising at least one battery cell;
a switch connected to the battery module according to a plurality of charge/discharge cycles; and
a battery life depletion prediction apparatus configured to:
measure a characteristic value of the battery cell in each of the plurality of charge/discharge cycles,
estimate a state of health (SoH) of the battery cell for each of the plurality of charge/discharge cycles using the characteristic value of the battery cell measured in each of the plurality of charge/discharge cycles,
generate an SoH differentiation curve representing a differentiation value of the SoH in each of the plurality of charge/discharge cycles, and
determine a point in time, at which the SoH differentiation curve and a threshold value for predicting the life deterioration point of the battery cell meet, as the life deterioration point of the battery cell.

13. The battery pack as claimed in claim 12, wherein the battery life depletion prediction apparatus is configured to set an average value of the differentiation values within a set charge/discharge cycle period of the SoH differentiation curve as the threshold value.

14. The battery pack as claimed in claim 13, wherein the set charge/discharge cycle period comprises a period from a first charge/discharge cycle of the plurality of charge/discharge cycles, or a charge/discharge cycle after an initial part of the plurality of charge/discharge cycles including at least the first charge/discharge cycle, to a charge/discharge cycle before derating occurs.

15. The battery pack as claimed in claim 12, further comprising a battery management system configured to control the switch and the battery module according to the plurality of charge/discharge cycles.
